(19) United States
(12) Patent Application Publication
(10) Pub. No.: US 2002/0132473 A1
(43) Pub. Date: Sep. 19, 2002

(54) Integrated barrier layer structure for copper contact level metallization

(75) Inventors: Tony Chiang, Santa Clara, CA (US); Peijun Ding, San Jose, CA (US); Barry Chin, Saratoga, CA (US)

Correspondence Address: Patent Counsel, Applied Materials, Inc., 3050 Bowers Avenue, P.O. Box 450A, Santa Clara, CA, 95052, US

(73) Assignee: Applied Materials ,Inc.

(21) Appl. No.: 09/805,865

(22) Filed: Mar. 13, 2001

(51) Int. Cl. H01L 21/4763

(52) U.S. Cl. 438/643

(57) ABSTRACT

A method for forming an integrated barrier layer structure that is compatible with copper (Cu) metallization schemes for integrated circuit fabrication is disclosed. In one aspect, an integrated circuit is metallized by forming an integrated barrier layer structure on a silicon substrate followed by deposition of one or more copper (Cu) layers. The integrated barrier layer structure includes one or more barrier layers selected from tantalum (Ta), tantalum nitride (TaNₓ), tungsten (W), and tungsten nitride (WNₓ) conformably deposited on the silicon substrate. After the one or more barrier layers are deposited on the silicon substrate, the silicon substrate is heated to form a silicide layer at the interface between the silicon substrate and the barrier layers.

### BACKGROUND OF THE DISCLOSURE

1. Field of the Invention

The present invention relates to contact level metallization schemes and, more particularly to barrier layers suited for contact level metallization schemes in integrated circuit fabrication.

2. Description of the Background Art

In the manufacture of integrated circuits, contact level metallization schemes are often used to provide low resistance contacts to an underlying semiconductor material. Typically, contact level metallization schemes combine an integrated barrier layer structure with a contact level metal layer.

For example, when a gate electrode of a transistor is fabricated, an integrated barrier layer structure (e. g. titanium/titanium nitride (Ti/TiN)) is formed between the gate material (e. g., polysilicon) and the contact level metal layer (e. g., aluminum (Al) or tungsten (W)) of the gate electrode. The Ti/TiN barrier layer inhibits the diffusion of the Al or W into the polysilicon gate material. Such Al or W diffusion is undesirable because it potentially changes the characteristics of the transistor, rendering the transistor inoperable.

However, at high temperatures (e. g., temperatures greater than about 400° C.) the Ti/TiN barrier layer may react with Al or W to form titanium aluminide (TiAlₓ) or titanium tungstide (TiWₓ). The formation of TiAlₓ or TiWₓ increases the resistance of the metallization level, degrading the overall performance (e. g., speed and reliability) of the integrated circuit.

Therefore, a need exists in the art for barrier layer/contact level metallization schemes suitable for use in integrated circuits.

### SUMMARY OF THE INVENTION

An integrated barrier layer structure compatible with copper metallization schemes used to fabricate integrated circuits is described. In one aspect, an integrated circuit is metallized by forming the integrated barrier layer structure on a silicon substrate followed by the deposition of one or more copper (Cu) layers.

The integrated barrier layer structure is formed by conformably depositing one or more barrier layers comprising tantalum (Ta), tantalum nitride (TaNₓ), tungsten (W), or tungsten nitride (WNₓ) on the silicon substrate. The one or more barrier layers are conformably deposited on the silicon substrate using physical vapor deposition (PVD) and/or chemical vapor deposition (CVD) techniques.

After the one or more barrier layers are conformably deposited on the silicon substrate, the silicon substrate is heated to form a silicide at the interface between the silicon substrate and the barrier layers. The silicide provides a low resistance contact to the silicon substrate.

Subsequent to the silicide formation, one or more copper layers are conformably deposited on the integrated barrier layer structure. The one or more copper layers are conformably deposited using electroplating, chemical vapor deposition (CVD), or physical vapor deposition (PVD) techniques, as well as combinations thereof.

In another aspect, an integrated circuit interconnect structure is fabricated. For such an embodiment, a preferred process sequence includes providing a silicon substrate having one or more dielectric layers thereon with apertures defined therein. Conformably depositing one or more barrier layers comprising tantalum (Ta), tantalum nitride (TaNₓ), tungsten (W), tungsten nitride (WNₓ), and combinations thereof on the surfaces of the apertures. After the one or more barrier layers are conformably deposited, heating the silicon substrate to form a low resistance silicide layer between the one or more barrier layers and the silicon substrate. Thereafter, the interconnect structure is completed when at least one copper layer is conformably deposited on the one or more barrier layers.

### BRIEF DESCRIPTION OF THE DRAWINGS

The teachings of the present invention can be readily understood by considering the following detailed description in conjunction with the accompanying drawings, in which:

FIG. 1 depicts a schematic illustration of an apparatus that can be used for the practice of this invention;

FIG. 2 depicts a schematic cross-sectional view of a sputtering type physical vapor deposition (PVD) chamber;

FIG. 3 depicts a schematic cross-sectional view of a chemical vapor deposition (CVD) chamber;

FIG. 4 depicts a schematic cross-sectional view of a rapid thermal processor (RTP) chamber; and

FIGS. 5a-5d illustrate schematic cross-sectional views of an interconnect structure at different stages of an integrated circuit fabrication sequence.

### DETAILED DESCRIPTION

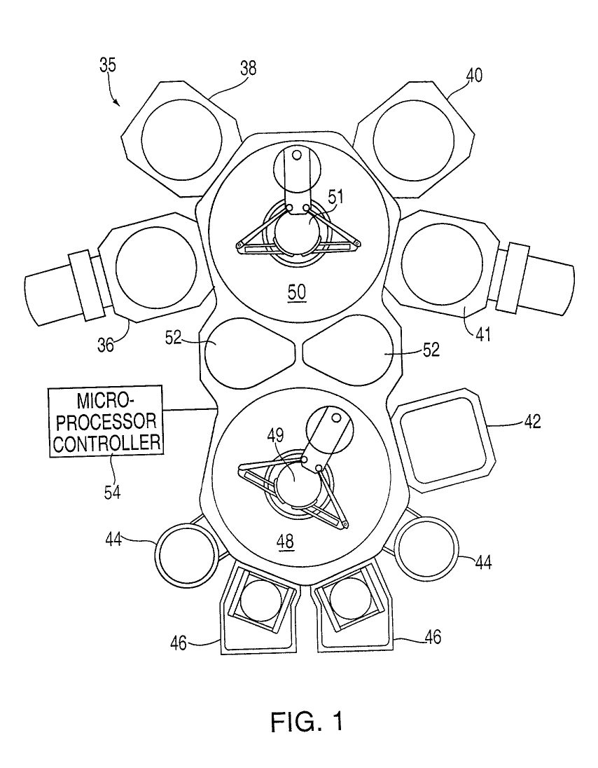

FIG. 1 is a schematic representation of a wafer processing system 35 that can be used to perform integrated circuit metallization in accordance with embodiments described herein. The wafer processing system 35 typically comprises process chambers 36, 38, 40, 41, degas chambers 44, load-lock chambers 46, transfer chambers 48, 50, pass-through chambers 52, a microprocessor controller 54, along with other hardware components such as power supplies (not shown) and vacuum pumps (not shown). An example of such a wafer processing system 35 is an ENDURA® System, commercially available from Applied Materials, Inc., Santa Clara, Calif.

Details of the wafer processing system 35 are described in commonly assigned U.S. Pat. No. 5,186,718, entitled, “Staged-Vacuum Substrate Processing System and Method”, issued on Feb. 16, 1993, and is hereby incorporated by reference. The salient features of the wafer processing system 35 are briefly described below.

The wafer processing system 35 includes two transfer chambers 48, 50, each containing a transfer robot 49, 51. The transfer chambers 48, 50 are separated one from the other by pass-through chambers 52.

Transfer chamber 48 is coupled to load-lock chambers 46, degas chambers 44, pre-clean chamber 42, and pass-through chambers 52. Substrates (not shown) are loaded into the wafer processing system 35 through load-lock chambers 46. Thereafter, the substrates are sequentially degassed and cleaned in degas chambers 44 and the pre-clean chamber 42, respectively. The transfer robot 49 moves the substrate between the degas chambers 44 and pre-clean chamber 42.

Transfer chamber 50 is coupled to a cluster of process chambers 36, 38, 40, 41. The cleaned substrates are moved from transfer chamber 48 into transfer chamber 50 via pass-through chambers 52. Thereafter, transfer robot 51 moves the substrates between one or more of the process chambers 36, 38, 40, 41.

The process chambers 36, 38, 40, 41 are used to perform various integrated circuit fabrication sequences. For example, process chambers 36, 38, 40, 41 may include physical vapor deposition (PVD) chambers, ionized metal plasma physical vapor deposition (IMP PVD) chambers, chemical vapor deposition (CVD) chambers, rapid thermal process (RTP) chambers, and anti-reflective coating (ARC) chambers, among others.

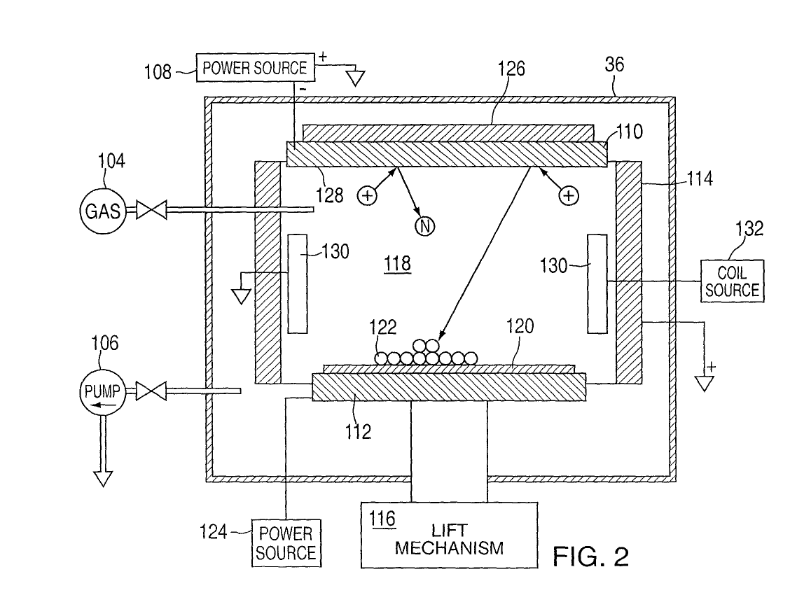

FIG. 2 depicts a schematic cross-sectional view of a sputtering-type physical vapor deposition (PVD) process chamber 36 of wafer processing system 35. An example of such a PVD process chamber 36 is an IMP VECTRA™ chamber, commercially available from Applied Materials, Inc., Santa Clara, Calif.

The PVD chamber 36 is coupled to a gas source 104, a pump system 106, and a target power source 108. The PVD chamber 36 encloses a target 110, a substrate 120 positioned on a vertically movable pedestal 112, and a shield 114 enclosing a reaction zone 118. A lift mechanism 116 is coupled to the pedestal 112 to position the pedestal 112 relative to the target 110.

The gas source 104 supplies a process gas into the PVD chamber 36. The process gas generally includes argon (Ar) or some other inert gas. The pump system 106 controls the pressure within the PVD chamber 36.

The target 110 is typically suspended from the top of the PVD chamber 36. The target 110 includes a material that is sputtered during operation of the wafer processing system 35. Although the target may comprise, as a material to be deposited, an insulator or semiconductor, the target 110 generally comprises a metal. For example, the target may be formed of tantalum (Ta), tungsten (W), copper (Cu), or other materials known in the art.

The pedestal 112 supports the substrate 120 within the PVD chamber 36. The pedestal is generally disposed at a fixed distance from the target 110 during processing. However, the distance between the target 110 and the substrate 120 may be varied during processing. The pedestal 112 is supported by the lift mechanism 116, which moves the pedestal 112 along a range of vertical motion within the PVD chamber 36.

The target power source 108 is used to infuse the process gas with energy and may comprise a DC source, a radio frequency (RF) source, or a DC-pulsed source. Applying either DC or RF power to the process gas creates an electric field in the reaction zone 118. The electric field ionizes the process gas in the reaction zone 118 to form a plasma comprising process gas ions, electrons, and process gas atoms (neutrals). Additionally, the electric field accelerates the process gas ions toward the target 110, for sputtering target particles from the target 110. When electrons in the plasma collide with the sputtered target particles, such target particles become ionized.

The PVD chamber 36 configuration enables deposition of sputtered and ionized target particles from the target 110 onto the substrate 120 to form a film 122 thereon. The shield 114 confines the sputtered particles and non-reactant gas in a reaction zone within the PVD chamber 36. As such, the shield 114 prevents deposition of target particles in unwanted locations, for example, beneath the pedestal 112 or behind the target 110.

The PVD chamber 36 may comprise additional components for improving the deposition of sputtered particles onto the substrate 120. For example, the PVD chamber 36 may include a bias power source 124 for biasing the substrate 120. The bias power source 124 is coupled to the pedestal 112 for controlling material layer deposition onto the substrate 120. The bias power source 124 is typically an AC source having a frequency of, for example, about 400 kHz.

When the bias power from the power source 124 is applied to the substrate 120, electrons in the plasma accumulate toward the substrate 120, creating a negative DC offset on the substrate 120 and the pedestal 112. The bias power applied to the substrate 120 attracts sputtered target particles that become ionized. These ionized target particles are generally attracted to the substrate 120 in a direction that is substantially perpendicular thereto. As such, the bias power source 124 enhances the deposition of target particles onto the substrate 120.

The PVD chamber 36 may also comprise a magnet 126 or magnetic sub-assembly positioned behind the target 110 for creating a magnetic field proximate to the target 110. The PVD chamber 36 may also comprise a coil 130 disposed within the shield 114 between the target 110 and the substrate 120. The coil 130 may comprise either a single-turn coil or a multi-turn coil that, when energized, ionizes the sputtered particles. This process is known as Ion Metal Plasma (IMP) deposition. The coil 130 is generally coupled to an AC source 132 having a frequency of, for example, about 2 MHz.

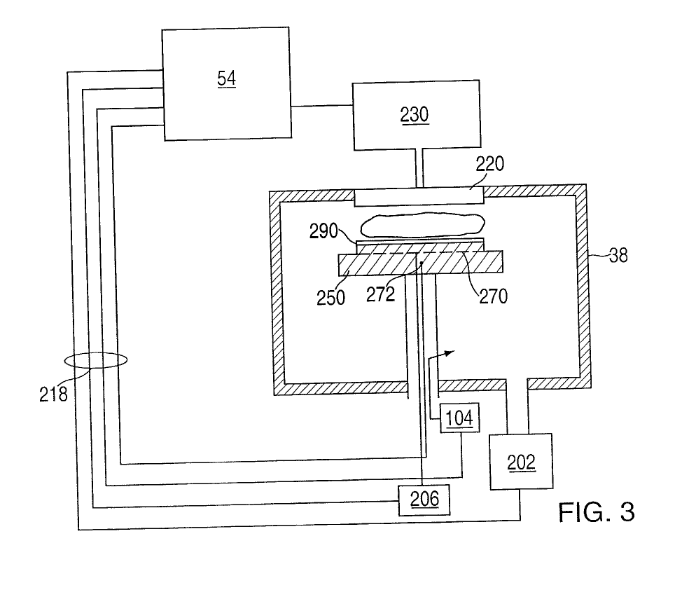

FIG. 3 depicts a schematic cross-sectional view of a chemical vapor deposition (CVD) process chamber 38 of wafer processing system 35. Examples of such CVD chambers 38 include TXZ™ chambers, WXZ™ chambers and PRECISION 5000® chambers, commercially available from Applied Materials, Inc., Santa Clara, Calif.

The CVD chamber 38 generally houses a wafer support pedestal 250, which is used to support a substrate 290. The wafer support pedestal 250 is movable in a vertical direction inside the CVD chamber 38 using a displacement mechanism (not shown).

Depending on the specific CVD process, the substrate 290 can be heated to some desired temperature prior to or during deposition. For example, the wafer support pedestal 250 may be heated by an embedded heater element 270. The wafer support pedestal 250 may be resistively heated by applying an electric current from an AC power supply 206 to the heater element 270. The substrate 290 is, in turn, heated by the pedestal 250.

A temperature sensor 272, such as a thermocouple, is also embedded in the wafer support pedestal 250 to monitor the temperature of the pedestal 250 in a conventional manner. The measured temperature is used in a feedback loop to control the AC power supply 206 for the heating element 270, such that the substrate temperature can be maintained or controlled at a desired temperature which is suitable for the particular process application. The wafer support pedestal 250 is optionally heated using radiant heat (not shown).

A vacuum pump 202 is used to evacuate the CVD chamber 38 and to maintain the proper gas flows and pressures inside the CVD chamber 38. A showerhead 220, through which process gases are introduced into the CVD chamber 38, is located above the wafer support pedestal 250. The showerhead 220 is connected to a gas panel 230, that controls and supplies various gases provided to the CVD chamber 38.

Proper control and regulation of the gas flows through the gas panel 230 is performed by mass flow controllers (not shown) and a microprocessor controller 54 (FIG. 1). The showerhead 220 allows process gases from the gas panel 230 to be uniformly introduced and distributed in the CVD chamber 38.

The CVD chamber 38 may comprise additional components for enhancing layer deposition on the substrate 290. For example, the showerhead 220 and wafer support pedestal 250 may also form a pair of spaced apart electrodes. When an electric field is generated between these electrodes, the process gases introduced into the CVD chamber 38 are ignited into a plasma.

Typically, the electric field is generated by coupling the wafer support pedestal 250 to a source of radio frequency (RF) power (not shown) through a matching network (not shown). Alternatively, the RF power source and matching network may be coupled to the showerhead 220, or coupled to both the showerhead 220 and the wafer support pedestal 250.

Plasma enhanced chemical vapor deposition (PECVD) techniques promote excitation and/or disassociation of the reactant gases by the application of the electric field to the reaction zone near the substrate surface, creating a plasma of reactive species. The reactivity of the species in the plasma reduces the energy required for a chemical reaction to take place, in effect lowering the required temperature for such PECVD processes.

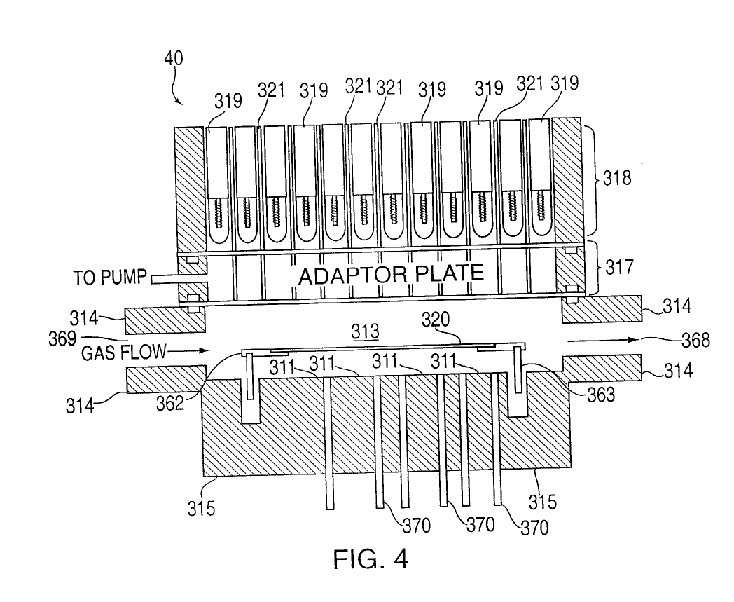

FIG. 4 depicts a schematic cross-sectional view of a rapid thermal processor (RTP) chamber 40 of wafer processing system 35. An example of a RTP chamber 40 is a CENTURA® chamber, commercially available from Applied Materials, Inc., Santa Clara, Calif.

The RTP chamber 40 includes sidewalls 314, a bottom 315, and a window assembly 317. The sidewalls 314 and the bottom 315 generally comprise a metal such as, for example, stainless steel. The upper portions of sidewalls 314 are sealed to window assembly 317 by o-rings 316. A radiant energy assembly 318 is positioned over and coupled to window assembly 317. The radiant energy assembly 318 includes a plurality of lamps 319 each mounted to a light pipe 321.

The RTP chamber 40 houses a substrate 320 supported around its perimeter by a support ring 362 made of, for example, silicon carbide. The support ring 362 is mounted on a rotatable cylinder 363. The rotatable cylinder 363 causes the support ring 362 and the substrate to rotate within the RTP chamber 40.

The bottom 315 of chamber 40 includes a gold-coated top surface 311, which reflects light energy onto the backside of the substrate 320. Additionally, the RTP chamber 40 includes a plurality of temperature probes 370 positioned through the bottom 315 of RTP camber 40 to detect the temperature of the substrate 320.

A gas inlet 369 through sidewall 314 provides process gases to the RTP chamber 40. A gas outlet 368 positioned through sidewall 314 opposite to gas inlet 369 removes process gases from the RTP chamber 40. The gas outlet 368 is coupled to a pump system (not shown) such as a vacuum source. The pump system exhausts process gases from the RTP chamber 40 and maintains a desired pressure therein during processing.

The radiant energy assembly 318 preferably is configured so the lamps 319 are positioned in a hexagonal array or in a “honeycomb” arrangement, above the surface area of the substrate 320 and the support ring 362. The lamps 319 are grouped in zones that may be independently controlled, to uniformly heat the substrate 320.

The window assembly 317 includes a plurality of short light pipes 341 that are aligned to the light pipes 321 of the radiant energy assembly 318. Radiant energy from the lamps 321 is provided via light pipes 321, 341 to the process region 313 of RTP chamber 40.

Referring to FIG. 1, the PVD process chamber 36, the CVD process chamber 38, and the RTP chamber 40 as described above are each controlled by a microprocessor controller 54. The microprocessor controller 54 may be one of any form of general purpose computer processor (CPU) that can be used in an industrial setting for controlling various chambers and sub-processors. The computer may use any suitable memory, such as random access memory, read only memory, floppy disk drive, hard disk, or any other form of digital storage, local or remote. Various support circuits may be coupled to the CPU for supporting the processor in a conventional manner. Software routines as required may be stored in the memory or executed by a second CPU that is remotely located.

The software routines are executed after the substrate is positioned on the pedestal. The software routines, when executed, transform the general purpose computer into a specific process computer that controls the chamber operation so that a chamber process is performed. Alternatively, the software routines may be performed in hardware, as an application specific integrated circuit or other type of hardware implementation, or a combination of software or hardware.

### Barrier Layer Structure Deposition

In one embodiment, an integrated circuit is metallized by forming an integrated barrier layer structure on a silicon substrate followed by deposition of one or more copper (Cu) layers. The integrated barrier layer structure is formed by conformably depositing one or more barrier layers comprising tantalum (Ta), tantalum nitride (TaNₓ), tungsten (W), or tungsten nitride (WNₓ) on the silicon substrate. The one or more barrier layers may be conformably deposited on the silicon substrate using physical vapor deposition (PVD) or chemical vapor deposition (CVD).

In general, the following deposition process parameters can be used to conformably form the barrier layers using PVD. The process parameters range from a wafer temperature of about 20° C. to about 300° C., a chamber pressure of about 1.0 torr to about 100 torr, a DC power of about 1 kilowatt to about 20 kilowatts, and a bias power of about 1 watt to about 500 watts.

Nitrogen (N₂) gas is provided to the PVD deposition chamber when a nitride based barrier layer is to be formed. When TaNₓ or WNₓ are formed N₂ gas with a flow rate in a range of about 100 sccm to about 2000 sccm may be provided to the PVD chamber.

Also, an inert gas such as helium (He) or argon (Ar) may be provided to the PVD deposition chamber to maintain the chamber at a desired chamber pressure. The inert gas may be provided to the deposition chamber at a flow rate in a range of about 100 sccm to about 5000 sccm.

The above PVD process parameters provide a deposition rate for the one or more barrier layers in a range of about 50 Å/min to about 500 Å/min.

Using CVD techniques, the one or more barrier layers may be formed by thermally decomposing a tungsten precursor or a tantalum-containing metal organic precursor. The tungsten precursor may be selected from tungsten hexafluoride (WF₆) and tungsten carbonyl (W(CO)₆). The tantalum-containing metal organic precursor may be selected, for example, from the group of pentakis(diethylamido) tantalum (PDEAT) (Ta(Net₂)₅), pentakis (ethylmethylamido) tantalum (PEMAT) (Ta(N(Et)(Me))₅), and pentakis(dimethylamido) tantalum (PDMAT) (Ta(Nme₂)₅), among others.

Carrier gases such as hydrogen (H₂), helium (He), argon (Ar), and nitrogen (N₂), among others may be mixed with the tantalum or tungsten precursors.

In general, the following process parameters can be used to form the one or more barrier layers using CVD techniques in a process chamber similar to that shown in FIG. 3. The process parameters range from a wafer temperature of less than about 450° C., a chamber pressure of about 1 torr to about 10 torr, a tantalum or tungsten precursor flow rate of about 50 sccm to about 7000 sccm, and a carrier gas flow rate of about 100 sccm to about 1 slm. The above process parameters typically provide a deposition rate for the CVD deposited one or more barrier layers in a range of about 10 Å/min. to about 200 Å/min.

After the one or more barrier layers are conformably deposited on the silicon substrate, the silicon substrate is heated to form a silicide layer at the interface between the silicon substrate and the barrier layers. The silicide layer comprises either tantalum silicide (TaSiₓ) or tungsten silicide (WSiₓ). The silicide layer provides a low resistance contact to the silicon substrate.

The silicide layer is formed by heating the silicon substrate using a rapid thermal process (RTP) chamber similar to that shown in FIG. 4, in the presence of an inert gas, such as helium (He) or argon (Ar). In general, the following process parameters can be used to form the silicide layer. The process parameters range from a wafer temperature of about 500° C. to about 1100° C., a chamber pressure of about 1 torr to about 100 torr, and an inert gas flow rate of about 200 sccm to about 5000 sccm, for a time less than about 600 seconds.

Alternatively, the TaNₓ or WNₓ may be formed in the RTP chamber by introducing the N₂ gas into the RTP chamber at temperatures in a range of about 50° C. to about 300° C., prior to, or during silicide formation.

The above process parameters are suitable for implementation on a 200 mm (millimeter) substrate in a deposition chamber available from Applied Materials, Inc., Santa Clara, Calif. Other deposition chambers are within the scope of the invention, and the parameters listed above may vary according to the particular deposition chambers used to form the silicide layer as well as the one or more barrier layers. For example, other deposition chambers may have a larger (e. g., chambers configured to accommodate 300 mm substrates) or a smaller volume, requiring gas flow rates, or powers that are larger or smaller than those recited for deposition chambers available from Applied Materials, Inc.

Subsequent to the silicide formation, one or more copper layers are conformably deposited on the integrated barrier layer structure. The one or more copper layers are conformably deposited using electroplating, chemical vapor deposition (CVD), physical vapor deposition (PVD), and/or combinations thereof. For example, a CVD copper layer may be deposited from a gas mixture containing Cu⁺²(hfac)₂ (copper hexafluoro acetylacetonate), Cu⁺²(fod)₂ (copper heptafluoro dimethyl octanediene), Cu⁺¹hfac TMVS (copper hexafluoro acetylacetonate trimethylvinylsilane), or combinations thereof. A copper layer may be electroplated from a copper sulfate electrolyte solution.

### Integrated Circuit Fabrication

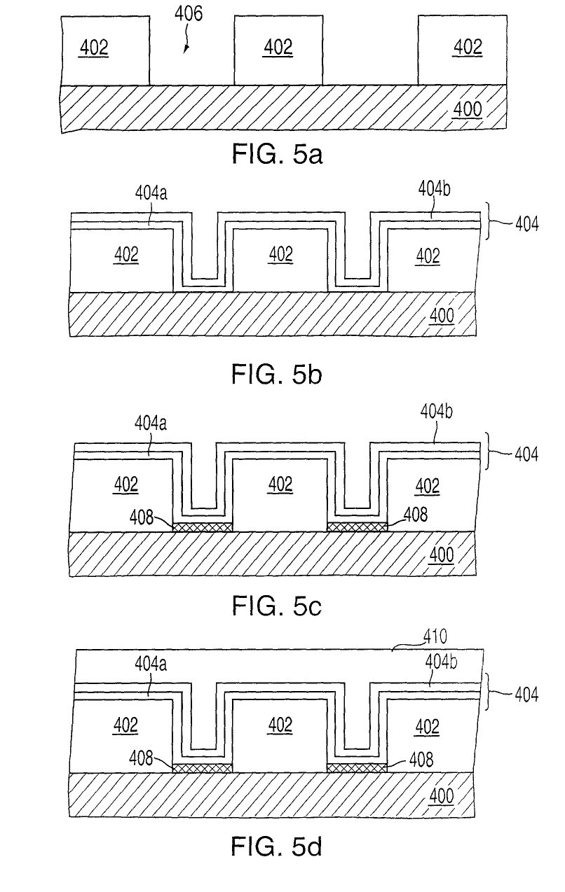

FIGS. 5a-5d illustrate schematic cross-sectional views of a substrate 400 at different stages of an interconnect fabrication sequence. Depending on the specific stage of processing, substrate 400 may include a silicon substrate with one or more material layers formed thereon. FIG. 5a, for example, illustrates a cross-sectional view of a substrate 400 having a dielectric layer 402 thereon. The dielectric layer may be an oxide (e. g., silicon dioxide, fluorosilicate glass (FSG). In general, the substrate 400 may comprise silicon, dielectrics, metals, or other materials.

FIG. 5a, for example, illustrates one embodiment in which the substrate 400 is silicon having a fluorosilicate glass layer formed thereon. The dielectric layer has a thickness of about 10,000 Å to about 20,000 Å, depending on the size of the structure to be fabricated.

The dielectric layer 402 has apertures 406 therethrough. The apertures 406 have diameters less than about 1.0 μm (micrometer), providing apertures with aspect ratios in a range of about 3:1 to about 4:1.

Referring to FIG. 5b, a barrier layer structure 404 comprising one or more barrier layers 404a, 404b is conformably deposited in the apertures 406, according to the process parameters described above. The one or more barrier layers are selected from Ta, TaNₓ, W, WNₓ, or combinations thereof.

The thickness of each of the one or more barrier layers comprising the barrier layer structure 404 is variable depending on the specific stage of processing. Typically, each of the one or more barrier layers has a thickness of about 200 Å to about 2000 Å.

After the barrier layer structure 404 is formed, the silicon substrate 400 is heated to form a silicide 408 at the interface between the silicon substrate 400 and the barrier layer structure 404, as depicted in FIG. 5c. The silicide layer 408 is formed by heating the silicon substrate 400 using a rapid thermal processor (RTP) according to the process parameters described above. The silicide is either TaSiₓ or WSiₓ. The silicide layer 406 has a thickness of about 50 Å to about 500 Å.

Referring to FIG. 5d, the interconnect structure is completed by filling the apertures 406 with a metal layer 410. The metal layer 410 may be a copper layer. The metal layer 410 has a thickness of about 500 Å to about 5,000 Å.

Although several preferred embodiments, which incorporate the teachings of the present invention, have been shown and described in detail, those skilled in the art can readily devise many other varied embodiments that still incorporate these teachings.

What is claimed is:

1. A device, comprising:
a substrate;
a barrier layer conformably formed on the substrate, wherein the barrier layer is selected from the group of tantalum suicide (TaSiₓ), tantalum nitride (TaNₓ), tungsten silicide (WSiₓ), tungsten nitride (WNₓ), and combinations thereof; and
a metal layer conformably formed on the barrier layer.

2. The device of claim 1 wherein the substrate has one or more material layers formed thereon.

3. The device of claim 2 wherein the one or more material layers are selected from the group of silicon dioxide (SiO₂), amorphous carbon, fluorinated amorphous carbon, parylene, fluorinated silicate glass (FSG), oxynitride, silicon carbide, and combinations thereof.

4. The device of claim 2 wherein the one or more material layers have apertures formed therein.

5. The device of claim 4 wherein the apertures are formed through the one or more material layers to the substrate surface.

6. The device of claim 4 wherein the apertures each have a diameter less than about 1 μm (micrometer).

7. The device of claim 1 wherein the barrier layer has a thickness in a range of about 50 Å to about 2000 Å.

8. The device of claim 1 wherein a copper metal layer is conformably formed on the barrier layer.

9. An interconnect structure, comprising:
a substrate;
one or more dielectric layers formed on the substrate, wherein the one or more dielectric layers have apertures therein;
a barrier layer conformably formed on the surfaces of the apertures, wherein the barrier layer is selected from the group of tantalum silicide (TaSiₓ), tantalum nitride (TaNₓ), tungsten silicide (WSiₓ), tungsten nitride (WNₓ), and combinations thereof; and
a metal layer conformably formed on the barrier layer.

10. The interconnect structure of claim 9 wherein the substrate has one or more material layers formed thereon.

11. The interconnect structure of claim 9 wherein the one or more dielectric layers are selected from the group of silicon dioxide (SiO₂), amorphous carbon, fluorinated amorphous carbon, parylene, fluorinated silicate glass (FSG), oxynitride, silicon carbide, and combinations thereof.

12. The interconnect structure of claim 9 wherein the apertures are formed through the one or more dielectric layers to the substrate surface.

13. The interconnect structure of claim 9 wherein the apertures each have a diameter less than about 1 μm (micrometer).

14. The interconnect structure of claim 9 wherein the barrier layer has a thickness in a range of about 50 Å to about 2000 Å.

15. The interconnect structure of claim 9 wherein a copper metal layer is conformably formed on the barrier layer.

16. A method of fabricating a device, comprising:
depositing a barrier layer conformably on a silicon substrate, wherein the barrier layer is selected from the group of tantalum (Ta), tantalum nitride (TaNₓ), tungsten (W), tungsten nitride (WNₓ) and combinations thereof;
forming a silicide at the interface between the barrier layer and the silicon substrate; and
depositing a metal layer conformably on the barrier layer.

17. The method of claim 16 wherein the substrate has one or more material layers thereon.

18. The method of claim 17 wherein the one or more material layers are selected from the group of silicon dioxide (SiO₂), amorphous carbon, fluorinated amorphous carbon, parylene, fluorinated silicate glass (FSG), oxynitride, silicon carbide, and combinations thereof.

19. The method of claim 17 wherein the one or more material layers have apertures therein.

20. The method of claim 19 wherein the apertures are formed through the one or more material layers to the substrate surface.

21. The method of claim 19 wherein the apertures each have a diameter less than about 1 μm (micrometer).

22. The method of claim 16 wherein the barrier layer has a thickness in a range of about 50 Å to about 2000 Å.

23. The method of claim 16 wherein a copper metal layer is deposited on the barrier layer.

24. The method of claim 16 wherein the barrier layer is deposited on the substrate by
positioning the substrate in a deposition chamber enclosing a target, wherein the target comprises a barrier layer material; and
generating an electric field in the deposition chamber, wherein the electric field sputters the barrier layer material from the target onto the substrate depositing the barrier layer thereon.

25. The method of claim 24 wherein the barrier layer material is formed in the presence of a nitrogen-containing atmosphere.

26. The method of claim 24 wherein the deposition chamber is maintained at a pressure between about 1.0 torr to about 100 torr.

27. The method of claim 24 wherein the deposition chamber is maintained at a temperature between about 20° C. to about 300° C.

28. The method of claim 24 wherein the electric field is generated by applying a radio frequency (RF) power to the target.

29. The method of claim 28 wherein the RF power is in a range of about 1 kilowatt to about 20 kilowatts.

30. The method of claim 24 wherein a bias power is applied to the substrate to conformably deposit the barrier layer thereon.

31. The method of claim 30 wherein the bias power is an AC power.

32. The method of claim 31 wherein the AC power is in a range of about 1 watt to about 500 watts.

33. The method of claim 16 wherein the barrier layer is deposited on the substrate by
positioning the substrate in a deposition chamber;
providing a gas mixture to the deposition chamber, wherein the gas mixture comprises a tungsten-containing precursor or a tantalum-containing precursor; and
thermally decomposing the gas mixture to deposit a tantalum-containing barrier layer or a tungsten-containing barrier layer on the substrate.

34. The method of claim 33 wherein the gas mixture is thermally decomposed at a temperature less than about 450° C.

35. The method of claim 33 wherein the tungsten-containing precursor is selected from the group of tungsten hexafluoride (WF₆) and tungsten carbonyl (W(CO)₆).

36. The method of claim 33 wherein the tantalum-containing precursor is selected from the group of pentakis(diethylamido) tantalum (PDEAT) (Ta(Net₂)₅), pentakis (ethylmethylamido) tantalum (PEMAT) (Ta(N(Et)(Me))₅), pentakis(dimethylamido) tantalum (PDMAT) (Ta(Nme₂)₅), and combinations thereof.

37. The method of claim 33 wherein the tungsten-containing precursor and the tantalum-containing precursor are each provided to the deposition chamber at flow rate in a range of about 50 sccm to about 7000 sccm.

38. The method of claim 33 wherein the deposition chamber is maintained at a pressure between about 1 torr to about 10 torr.

39. The method of claim 33 wherein the gas mixture further comprises a nitrogen-containing gas.

40. The method of claim 33 wherein the gas mixture further comprises a carrier gas.

41. The method of claim 33 wherein the carrier gas is selected from the group of hydrogen (H₂), helium (He), argon (Ar), nitrogen (N₂), and combinations thereof.

42. The method of claim 16 wherein the silicide is formed by heating the substrate at a temperature in a range of about 500° C. to about 1100° C.

43. A method of fabricating an interconnect structure, comprising:
providing a silicon substrate with one or more dielectric layers formed thereon, wherein the one or more dielectric layers have apertures therethrough to the surface of the silicon substrate;
depositing a barrier layer conformably on the surfaces of the apertures, wherein the barrier layer is selected from the group of tantalum (Ta), tantalum nitride (TaNₓ), tungsten (W), tungsten nitride (WNₓ) and combinations thereof;
forming a silicide between the barrier layer and the silicon substrate; and
depositing a metal layer conformably on the barrier layer.

44. The method of claim 43 wherein the substrate has one or more material layers formed thereon.

45. The method of claim 43 wherein the one or more dielectric layers are selected from the group of silicon dioxide (SiO₂), amorphous carbon, fluorinated amorphous carbon, parylene, fluorinated silicate glass (FSG), oxynitride, silicon carbide, and combinations thereof.

46. The method of claim 43 wherein the apertures each have a diameter less than about 1 μm (micrometer).

47. The method of claim 43 wherein the barrier layer has a thickness in a range of about 50 Å to about 2000 Å.

48. The method of claim 43 wherein a copper metal layer is deposited conformably on the barrier layer.

49. The method of claim 43 wherein the barrier layer is conformably deposited on the surfaces of the apertures formed in the one or more dielectric layers by
positioning the silicon substrate in a deposition chamber enclosing a target, wherein the target comprises barrier layer material; and
generating an electric field in the deposition chamber, wherein the electric field sputters barrier layer material from the target on the surfaces of the apertures formed in the one or more dielectric layers to deposit the barrier layer thereon.

50. The method of claim 49 wherein the electric field sputters the barrier layer material in the presence of a nitrogen-containing atmosphere.

51. The method of claim 49 wherein the deposition chamber is maintained at a pressure between about 1.0 torr to about 10 torr.

52. The method of claim 49 wherein the deposition chamber is maintained at a temperature between about 20° C. to about 300° C.

53. The method of claim 49 wherein the electric field is generated by applying a radio frequency (RF) power to the target.

54. The method of claim 53 wherein the RF power is in a range of about 1 kilowatt to about 20 kilowatts.

55. The method of claim 49 wherein a bias power is applied to the silicon substrate to conformably deposit the barrier layer thereon.

56. The method of claim 55 wherein the bias power is an AC power.

57. The method of claim 56 wherein the AC power has a frequency in a range of about 1 watt to about 500 watts.

58. The method of claim 43 wherein the barrier layer is deposited on the substrate by
positioning the substrate in a deposition chamber;
providing a gas mixture to the deposition chamber, wherein the gas mixture comprises a tungsten-containing precursor or a tantalum-containing precursor; and
thermally decomposing the gas mixture to deposit a tantalum-containing barrier layer or a tungsten-containing barrier layer on the substrate.

59. The method of claim 58 wherein the gas mixture is thermally decomposed at a temperature less than about 450° C.

60. The method of claim 58 wherein the tungsten-containing precursor is selected from the group of tungsten hexafluoride (WF₆) and tungsten carbonyl (W(CO)₆).

61. The method of claim 58 wherein the tantalum-containing precursor is selected from the group of pentakis(diethylamido) tantalum (PDEAT) (Ta(Net₂)₅), pentakis (ethylmethylamido) tantalum (PEMAT) (Ta(N(Et)(Me))₅), pentakis(dimethylamido) tantalum (PDMAT) (Ta(Nme₂)₅), and combinations thereof.

62. The method of claim 58 wherein the tungsten-containing precursor and the tantalum-containing precursor are each provided to the deposition chamber at flow rate in a range of about 50 sccm to about 7000 sccm.

63. The method of claim 58 wherein the deposition chamber is maintained at a pressure between about 1 torr to about 10 torr.

64. The method of claim 58 wherein the gas mixture further comprises a nitrogen-containing gas.

65. The method of claim 58 wherein the gas mixture further comprises a carrier gas.

66. The method of claim 58 wherein the carrier gas is selected from the group of hydrogen (H₂), helium (He), argon (Ar), nitrogen (N₂), and combinations thereof.

67. The method of claim 34 wherein the silicide is formed by heating the substrate at a temperature in a range of about 500° C. to about 1100° C.

68. A computer readable storage medium containing a software routine that, when executed, causes a general purpose computer to control a deposition chamber using a method of thin film deposition comprising:
depositing a barrier layer conformably on a silicon substrate, wherein the barrier layer is selected from the group of tantalum (Ta), tantalum nitride (TaNₓ), tungsten (w), tungsten nitride (WNₓ), and combinations thereof;
forming a silicide between the barrier layer and the silicon substrate; and
depositing a metal layer conformably on the barrier layer.

69. The computer readable storage medium of claim 68 wherein the barrier layer is conformably deposited on the silicon substrate by
positioning the substrate in a deposition chamber enclosing a target, wherein the target comprises a barrier layer material; and
generating an electric field in the deposition chamber, wherein the electric field sputters barrier layer material from the target onto the substrate to deposit the barrier layer thereon.

70. The computer readable storage medium of claim 69 wherein the barrier layer material is sputtered in the presence of a nitrogen-containing atmosphere.

71. The computer readable storage medium of claim 68 wherein the barrier layer is deposited on the substrate by
positioning the substrate in a deposition chamber;
providing a gas mixture to the deposition chamber, wherein the gas mixture comprises a tungsten-containing precursor or a tantalum-containing precursor; and
thermally decomposing the gas mixture to deposit a tantalum-containing barrier layer or a tungsten-containing barrier layer on the substrate.

72. The computer readable storage medium of claim 71 wherein the gas mixture further comprises a nitrogen source.

73. The computer readable storage medium of claim 68 wherein the suicide is formed by heating the substrate at a temperature in a range of about 500° C. to about 1100° C.
